(19) United States
(12) Patent Application Publication
(10) Pub. No.: US 2026/0371723 A1
(43) Pub. Date: Nov. 19, 2026

(54) SEMICONDUCTOR DEVICES WITH SEPARATION STRUCTURE

(71) Applicant: Samsung Electronics Co., Ltd., Suwon-si (KR)

(72) Inventors: Sangwoo HAN, Suwon-si (KR); Sungil PARK, Suwon-si (KR); Jae Hyun PARK, Suwon-si (KR); Juhun PARK, Suwon-si (KR); Younghoon LEE, Suwon-si (KR)

(21) Appl. No.: 19/416,451

(22) Filed: Dec. 11, 2025

(30) Foreign Application Priority Data
May 13, 2025 (KR) 10-2025-0062182

(51) Int. Cl. H10D 84/85; H10D 84/01

(52) U.S. Cl. CPC H10D 84/856; H10D 84/0186; H10D 84/0188; H10D 84/851

(57) ABSTRACT

A semiconductor device includes a first lower source/drain pattern, a second lower source/drain pattern adjacent in a first direction to the first lower source/drain pattern, a first upper source/drain pattern overlapping the first lower source/drain pattern, a second upper source/drain pattern overlapping the second lower source/drain pattern, a lower separation pattern between the first and second lower source/drain patterns, an upper separation pattern between the first and second upper source/drain patterns, and a through via in contact with the upper separation pattern and spaced apart from the lower separation pattern. The upper separation pattern and the lower separation pattern comprise different insulating materials.

### CROSS-REFERENCE TO RELATED APPLICATIONS

This U.S. non-provisional patent application claims priority under 35 U.S.C. §119 to Korean Patent Application No. 10-2025-0062182, filed on May 13, 2025, in the Korean Intellectual Property Office, the entire contents of which are hereby incorporated by reference.

### BACKGROUND

A semiconductor device includes an integrated circuit composed of MOS (Metal Oxide Semiconductor) field effect transistors (MOSFET). As the size and design rule of the semiconductor device gradually shrink, a scale down of the MOS field effect transistors is also gradually accelerating. As the size of the MOS field effect transistors shrinks, operating characteristics of the semiconductor device may deteriorate. Accordingly, various methods have been studied for forming the semiconductor device with better performance while overcoming limitations due to high integration of the semiconductor device.

### SUMMARY

According to some aspects of the present disclosure, a semiconductor device may include a first lower source/drain pattern; a second lower source/drain pattern adjacent in a first direction to the first lower source/drain pattern; a first upper source/drain pattern overlapping the first lower source/drain pattern; a second upper source/drain pattern overlapping the second lower source/drain pattern; a lower separation pattern between the first and second lower source/drain patterns; an upper separation pattern between the first and second upper source/drain patterns; and a through via in contact with the upper separation pattern and spaced apart from the lower separation pattern. The upper separation pattern and the lower separation pattern may comprise different insulating materials.

According to some aspects of the present disclosure, a semiconductor device may include a first source/drain structure; a second source/drain structure adjacent in a first direction to the first source/drain structure; a third source/drain structure adjacent to the first source/drain structure in a second direction intersecting the first direction; a separation structure between the first and second source/drain structures; semiconductor patterns connected to the third source/drain structure; a gate structure overlapping the semiconductor patterns; a cutting structure between the gate structure and the separation structure; and a through via penetrates the cutting structure.

According to some aspects of the present disclosure, a semiconductor device may include a first lower source/drain pattern; a second lower source/drain pattern adjacent to the first lower source/drain pattern in a first direction; a third lower source/drain pattern adjacent to the first lower source/drain pattern in a second direction intersecting the first direction; a first upper source/drain pattern overlapping with the first lower source/drain pattern; a second upper source/drain pattern overlapping the second lower source/drain pattern; a third upper source/drain pattern overlapping with the third lower source/drain pattern; a lower separation pattern between the first and second lower source/drain patterns; an upper separation pattern between the first and second upper source/drain patterns; lower semiconductor patterns connected to the third lower source/drain pattern; upper semiconductor patterns connected to the third upper source/drain pattern; a gate structure overlapping the lower semiconductor patterns and the upper semiconductor patterns; and a through via between the first and third lower source/drain patterns, between the first and a third upper source/drain patterns, between the lower separation pattern and the gate structure, and between the upper separation pattern and the gate structure.

According to some aspects of the present disclosure, a method of manufacturing a semiconductor device may include forming semiconductor patterns; forming source/drain structures connected to the semiconductor patterns, the source/drain structures comprise a first source/drain structure, a second source/drain structure adjacent in a first direction to the first source/drain structure, and a third source/drain structure adjacent in a second direction intersecting the first direction to the second source/drain structure; forming gate structures; forming a separation structure between the first and second source/drain structures; etching the separation structure to form a hole; and forming a through via in the hole.

In some implementations, the method of manufacturing the semiconductor device may further include forming a cutting structure between the first and third source/drain structures. Forming the hole may include etching the cutting structure and the separation structure together.

In some implementations, forming the separation structure may include: forming a preliminary separation layer; etching the preliminary separation layer to form a lower separation pattern; and forming an upper separation pattern on the lower separation pattern.

In some implementations, forming the hole may include etching the upper separation pattern.

In some implementations, the cutting structure may include a first cutting insulating layer and a second cutting insulating layer in the first cutting insulating layer. Forming the hole may include etching the second cutting insulating layer and the upper separation pattern together.

In some implementations, the second cutting insulating layer and the upper separation pattern may include an oxide.

In some implementations, forming the separation structure may include: removing a gate structure between the first and second source/drain patterns of the gate structures; and removing semiconductor patterns between the first and the second source/drain patterns of the semiconductor patterns.

### BRIEF DESCRIPTION OF THE DRAWINGS

FIG. 1A is a top view of an example of a semiconductor device.

FIG. 1B is a cross-sectional view taken along a line A1-A1′ in FIG. 1A.

FIG. 1C is a cross-sectional view taken along a line A2-A2′ in FIG. 1A.

FIG. 1D is a cross-sectional view taken along a line A3-A3′ in FIG. 1A.

FIG. 1E is an enlarged view of a Q1 region of FIG. 1D.

FIGS. 2A, 2B, 3A, 3B, 4A, 4B, 5A, 5B, 6A, 6B, 7A, 7B, 8A, 8B, 9A, 9B, 10A, 10B, 11A, 11B, 12A, 12B, and 12C are diagrams illustrating an example of a method of manufacturing a semiconductor device.

FIG. 13 is a cross-sectional view of an example of a semiconductor device.

### DETAILED DESCRIPTION

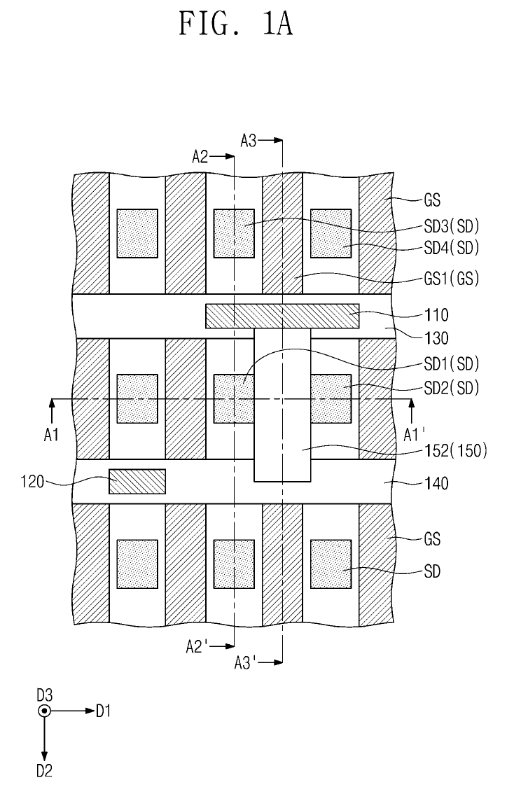

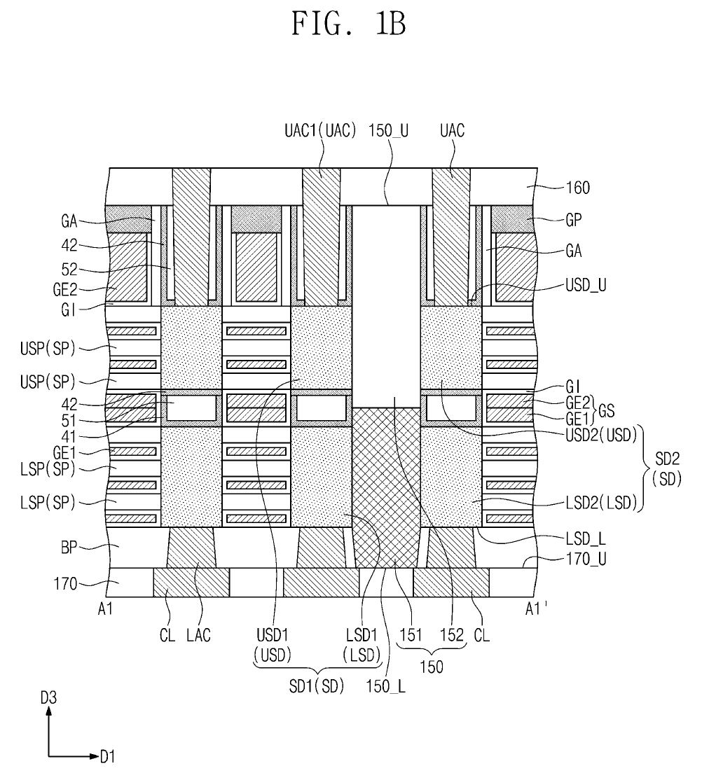

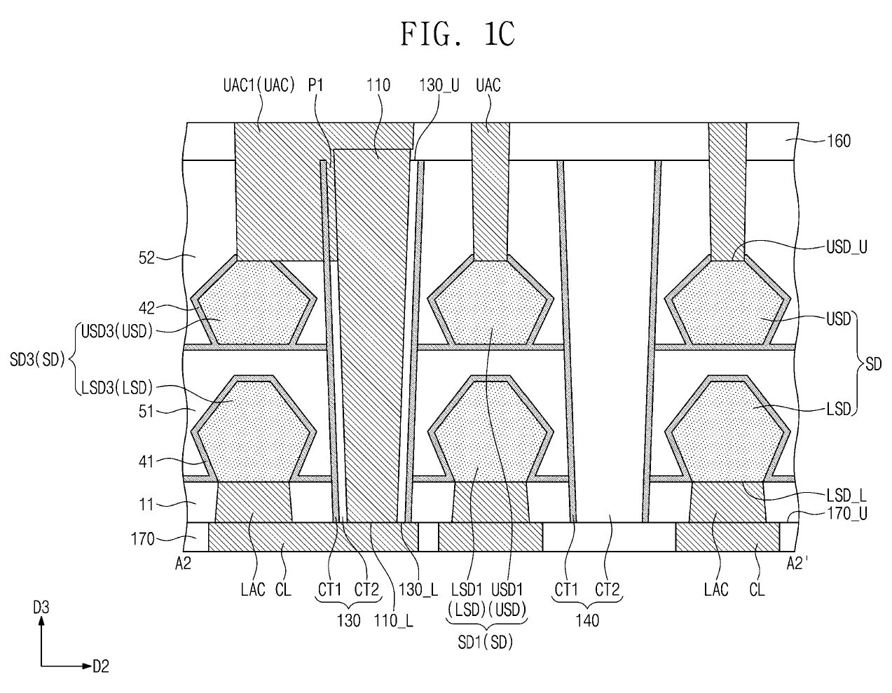

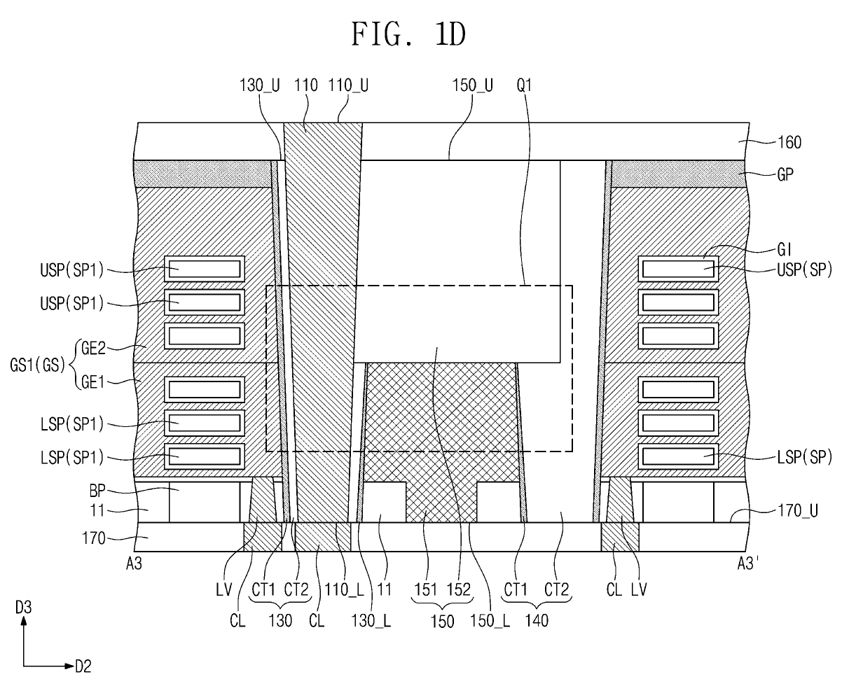

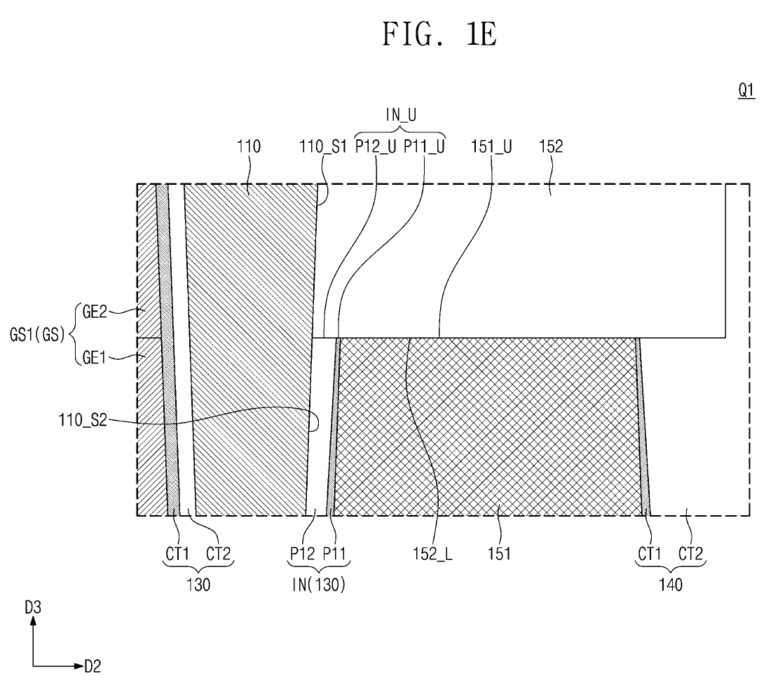

FIG. 1A is a top view of an example of a semiconductor device. FIG. 1B is a cross-sectional view taken along a line A1-A1′ in FIG. 1A. FIG. 1C is a cross-sectional view taken along a line A2-A2′ in FIG. 1A. FIG. 1D is a cross-sectional view taken along a line A3-A3′ in FIG. 1A. FIG. 1E is an enlarged view of a Q1 region of FIG. 1D.

Referring to FIGS. 1A, 1B, 1C, and 1D, the semiconductor device may include a logic cell. The logic cell in the present disclosure may mean a logic device (e.g., AND, OR, XOR, XNOR, inverter, etc.) that performs a specific function. The logic cell may include transistors that constitute the logic device.

A base pattern BP may be provided. The base pattern BP may extend in a first direction D1. Base patterns BP may be arranged to be spaced apart from each other in a second direction D2. The first direction D1 and the second direction D2 may intersect with each other. As an example, the first direction D1 and the second direction D2 may be horizontal directions orthogonal to each other.

In some implementations, a substrate connecting the base pattern BP may be provided. In this case, the substrate may be, for example, a semiconductor substrate, an insulator substrate, or a semiconductor-on-insulator (SOI) substrate.

In some implementations, the base pattern BP may include a semiconductor material. In some implementations, the base pattern BP may include an insulating material.

A device isolation layer 11 may be provided. The device isolation layer 11 may surround the base pattern BP. The device isolation layer 11 may be between the base patterns BP, e.g., filling spaces between the base patterns BP. The device isolation layer 11 may include an insulating material. For example, the device isolation layer 11 may include an oxide. In some implementations, the device isolation layer 11 may be a multiple layer including a plurality of insulating layers.

A semiconductor pattern SP may be provided. The semiconductor pattern SP may overlap the base pattern BP in the third direction D3. The semiconductor patterns SP may include semiconductor patterns SP overlapping with each other in a third direction D3. The third direction D3 may intersect the first direction D1 and the second direction D2. As an example, the third direction D3 may be a vertical direction orthogonal to the first direction D1 and the second direction D2.

The semiconductor pattern SP may include a crystalline semiconductor material. The semiconductor pattern SP may include, for example, silicon or silicon-germanium.

Although the number of the semiconductor patterns SP overlapping with each other in the third direction D3 is shown to be six, the number is not limited thereto. In some implementations, the number of semiconductor patterns SP overlapping each other in the third direction D3 may be five or less, or may be seven or more.

A source/drain structure SD may be provided. The source/drain structure SD may overlap the base pattern BP in the third direction D3. The source/drain structure SD may be provided on the base pattern BP. A plurality of the source/drain structures SD overlapping one base pattern BP in the third direction D3 may be arranged to be spaced apart from each other in the first direction D1. The source/drain structure SD may be disposed between the semiconductor patterns SP adjacent to each other in the first direction D1.

The source/drain structure SD may include a lower source/drain pattern LSD and an upper source/drain pattern USD. The lower source/drain pattern LSD and the upper source/drain pattern USD may overlap in the third direction D3. The lower source/drain pattern LSD and the upper source/drain pattern USD may be spaced apart in the third direction D3. The lower source/drain pattern LSD may be disposed at a lower level than the upper source/drain pattern USD.

The lower source/drain pattern LSD and the upper source/drain pattern USD may be epitaxial pattern formed by a selective epitaxial growth (SEG) process. The lower source/drain pattern LSD and the upper source/drain pattern USD may comprise silicon or silicon-germanium. The lower source/drain pattern LSD and the upper source/drain pattern USD may be doped with dopants.

In some implementations, the lower source/drain pattern LSD and the upper source/drain pattern USD may be doped with different dopants. As an example, the lower source/drain pattern LSD may be doped with a P-type dopant, and the upper source/drain pattern USD may be doped with an N-type dopant.

The source/drain structures SD may include a first source/drain structure SD1, a second source/drain structure SD2 adjacent to the first source/drain structure SD1 in the first direction D1, a third source/drain structure SD3 adjacent to the first source/drain structure SD1 in the second direction D2, and a fourth source/drain structure SD4 adjacent to the second source/drain structure SD2 in the second direction D2. The fourth source/drain structure SD4 may be adjacent to the third source/drain structure SD3 in the first direction D1.

The first source/drain structure SD1 may include a first lower source/drain pattern LSD1 and a first upper source/drain pattern USD1. The second source/drain structure SD2 may include a second lower source/drain pattern LSD2 and a second upper source/drain pattern USD2. The third source/drain structure SD3 may include a third lower source/drain pattern LSD3 and a third upper source/drain pattern USD3.

The semiconductor patterns SP may include lower semiconductor pattern LSP and upper semiconductor pattern USP. The lower semiconductor pattern LSP may be connected to the lower source/drain pattern LSD. The lower semiconductor pattern LSP may be in contact with the lower source/drain pattern LSD. The upper semiconductor pattern USP may be connected to the upper source/drain pattern USD. The upper semiconductor pattern USP may be in contact with the upper source/drain pattern USD. The lower semiconductor pattern LSP and the upper semiconductor pattern USP may overlap each other in the third direction D3. The lower semiconductor pattern LSP may be disposed at a lower level than the upper semiconductor pattern USP.

A lower liner 41 may be provided on the lower source/drain pattern LSD and the device isolation layer 11. The lower liner 41 may comprise an insulating material. In some implementations, the lower liner 41 may comprise nitride. In some implementations, the lower liner 41 may be a multiple layer including a plurality of insulating layers.

A first interlayer insulating layer 51 may be provided on the lower liner 41. The first interlayer insulating layer 51 may include an insulating material. For example, the first interlayer insulating layer 51 may include an oxide. In some implementations, the first interlayer insulating layer 51 may be a multiple layer including a plurality of insulating layers.

An upper liner 42 may be provided on the upper source/drain pattern USD. The upper liner 42 may comprise an insulating material. In some implementations, the upper liner 42 may comprise nitride. In some implementations, the upper liner 42 may be a multiple layer including a plurality of insulating layers.

The upper liner 42 may include a portion interposed between the first interlayer insulating layer 51 and the upper source/drain pattern USD.

A second interlayer insulating layer 52 may be provided on the upper liner 42. The second interlayer insulating layer 52 may include an insulating material. For example, the second interlayer insulating layer 52 may include an oxide. In some implementations, the second interlayer insulating layer 52 may be a multiple layer including a plurality of insulating layers.

A gate structure GS may be provided. The gate structure GS may overlap the semiconductor pattern SP in the third direction D3. The gate structures GS may be arranged to be spaced apart from each other along the first direction D1. The upper source/drain pattern USD and the lower source/drain patterns LSD may be provided between two gate structures GS adjacent to each other in the first direction D1.

The gate structure GS may include a lower gate electrode GE1 and an upper gate electrode GE2. The lower gate electrode GE1 may be disposed between two lower source/drain patterns LSD adjacent to each other in the first direction D1. The lower gate electrode GE1 may be disposed at the same level as the lower source/drain pattern LSD. The lower gate electrode GE1 may include a portion interposed between the lower semiconductor patterns LSP. The lower gate electrode GE1 may be disposed at the same level as the lower semiconductor pattern LSP.

The upper gate electrode GE2 may be disposed between two upper source/drain patterns USD adjacent to each other in the first direction D1. The upper gate electrode GE2 may be disposed at the same level as the upper source/drain pattern USD. The upper gate electrode GE2 may include a portion interposed between the upper semiconductor patterns USP. The upper gate electrode GE2 may be disposed at the same level as the upper semiconductor pattern USP.

The upper gate electrode GE2 may be provided on the lower gate electrode GE1. An upper surface of the lower gate electrode GE1 and a lower surface of the upper gate electrode GE2 may be in contact with each other. In some implementations, the lower gate electrode GE1 and the upper gate electrode GE2 may include different conductive materials. In some implementations, the lower gate electrode GE1 and the upper gate electrode GE2 may include the same conductive material. In some implementations, the lower gate electrode GE1 and the upper gate electrode GE2 may be connected without boundaries to have an integral structure.

The gate structure GS and the semiconductor pattern SP may constitute a three-dimensional field effect transistor (e.g., a multi-bridge-channel field-effect transistor (MBCFET) or gate all around field-effect transistor (GAAFET)).

A gate insulating layer GI may be provided. The gate insulating layer GI may be in contact with the gate structure GS. The gate insulating layer GI may separate the gate structure GS from the semiconductor pattern SP. The gate insulating layer GI may include an insulating material. For example, the gate insulating layer GI may include an oxide. In some implementations, the gate insulating layer GI may be a multiple layer including a plurality of insulating layers.

A gate spacer GA may be provided. A pair of gate spacers GA may be provided on both sides of the upper gate electrode GE2. The gate spacer GA may include an insulating material. In some implementations, the gate spacer GA may be a multiple layer structure including a plurality of insulating layers.

A gate capping pattern GP may be provided. The gate capping pattern GP may be provided on the upper gate electrode GE2. The gate capping pattern GP may be provided between the gate spacers GA. The gate capping pattern GP may include an insulating material. In some implementations, the gate capping pattern GP may be a multiple layer including a plurality of insulating layers.

A first cutting structure 130 and a second cutting structure 140 may be provided. The first cutting structure 130 and the second cutting structure 140 may extend in the first direction D1. The first cutting structure 130 and the second cutting structure 140 may be spaced apart from each other in the second direction D2. Each of the first cutting structure 130 and the second cutting structure 140 may be disposed between the gate structures GS adjacent to each other in the second direction D2. Each of the first cutting structure 130 and the second cutting structure 140 may be disposed between the source/drain structures SD adjacent to each other in the second direction D2.

The first cutting structure 130 and the second cutting structure 140 may penetrate the device isolation layer 11, the lower liner 41, the first interlayer insulating layer 51, the upper liner 42, and the second interlayer insulating layer 52 in the third direction D3. The first cutting structure 130 may be provided between the first and third source/drain structures SD1 and SD3, and between the second and fourth source/drain structures SD2 and SD4. The first cutting structure 130 may be provided between the first and third lower source/drain patterns LSD1 and LSD3, and between the first and the third upper source/drain pattern USD1 and USD3.

Each of the first cutting structure 130 and the second cutting structure 140 may include a first cutting insulating layer CT1 and a second cutting insulating layer CT2. The second cutting insulating layer CT2 may be provided in the first cutting insulating layer CT1. The second cutting insulating layer CT2 may be surrounded by the first cutting insulating layer CT1.

The first cutting insulating layer CT1 may be in contact with the device isolation layer 11, the lower liner 41, the first interlayer insulating layer 51, the upper liner 42, and the second interlayer insulating layer 52. The second cutting insulating layer CT2 may be spaced apart from the device isolation layer 11, the lower liner 41, the first interlayer insulating layer 51, the upper liner 42, and the second interlayer insulating layer 52 by the first cutting insulating layer CT1.

The first cutting insulating layer CT1 may be in contact with the gate structure GS, the gate capping pattern GP, and the gate insulating layer GI. The second cutting insulating layer CT2 may be spaced apart from the gate structure GS, the gate capping pattern GP, and the gate insulating layer GI by the first cutting insulating layer CT1.

The first cutting insulating layer CT1 and the second cutting insulating layer CT2 may include different insulating materials. As an example, the first cutting insulating layer CT1 may include nitride, and the second cutting insulating layer CT2 may include oxide.

A separation structure 150 may be provided. The separation structure 150 may be provided between the first cutting structure 130 and the second cutting structure 140. The separation structure 150 may extend in the second direction D2. The separation structure 150 may be provided between the gate structures GS adjacent to each other in the second direction D2. The separation structure 150 may be provided between the first source/drain structure SD1 and the second source/drain structure SD2 adjacent to each other in the first direction D1. The separation structure 150 may be provided between the first and second lower source/drain patterns LSD1 and LSD2 adjacent to each other in the first direction D1, and the first and second upper source/drain pattern USD1 and USD2 adjacent to each others in the first direction D1.

The separation structure 150 may be in contact with the first cutting insulating layer CT1 and the second cutting insulating layer CT2 of the first cutting structure 130, the first cutting insulating layers CT1 and the second cutting insulating layer CT2 of the second cutting structure 140, the device isolation layer 11, the upper liner 42, the lower liner 41, and the base pattern BP. The separation structure 150 may be connected to the first and second lower source/drain patterns LSD1 and LSD2. The separation structure 150 may be in contact with the first and second lower source/drain patterns LSD1 and LSD2. The separation structure 150 may be connected to the first and second upper source/drain patterns USD1 and USD2. The separation structure 150 may be in contact with the first and second upper source/drain patterns USD1 and USD2.

The separation structure 150 may penetrate the device isolation layer 11, the lower liner 41, the first interlayer insulating layer 51, the upper liner 42, and the second interlayer insulating layer 52 in the third direction D3.

The separation structure 150 may include a lower separation pattern 151 and an upper separation pattern 152 on the lower separation pattern 151. The lower separation pattern 151 may be provided between the first and second lower source/drain patterns LSD1 and LSD2. The lower separation pattern 151 may be connected to the first and second lower source/drain patterns LSD1 and LSD2. The lower separation pattern 151 may be in contact with the first and second lower source/drain patterns LSD1 and LSD2. The lower separation pattern 151 may be disposed at the same level as the first and second lower source/drain patterns LSD1 and LSD2. The lower separation pattern 151 may be in contact with the lower liner 41 and may be spaced apart from the upper liner 42. The lower separation pattern 151 may be in contact with the device isolation layer 11. The lower separation pattern 151 may be in contact with the second cutting insulating layer CT2 and may be spaced apart from the first cutting insulating layer CT1.

The upper separation pattern 152 may be provided between the first and second upper source/drain patterns USD1 and USD2. The upper separation pattern 152 may be connected to the first and second upper source/drain patterns USD1 and USD2. The upper separation pattern 152 may be in contact with the first and second upper source/drain patterns USD1 and USD2. The upper separation pattern 152 may be disposed at the same level as the first and second upper source/drain patterns USD1 and USD2. The upper separation pattern 152 may be in contact with the lower liner 41 and the upper liner 42. The upper separation pattern 152 may be in contact with the second cutting insulating layer CT2 and the first cutting insulating layer CT1.

The lower separation pattern 151 may be disposed at a lower level than the upper separation pattern 152. A width of the lower separation pattern 151 in the second direction D2 may be smaller than that of the upper separation pattern 152 in the second direction D2. The lower separation pattern 151 and the upper separation pattern 152 may include different insulating materials. As an example, the lower separation pattern 151 may include a nitride (e.g., SiN), and the upper separation pattern 152 may include oxide (e.g., SiO or Tonen SilaZene (TOSZ)).

The lower separation pattern 151 may apply compressive stress to the first and second lower source/drain patterns LSD1 and LSD2. The upper separation pattern 152 may apply tensile stress to the first and second upper source/drain patterns USD1 and USD2.

In some implementations, the lower separation pattern 151 and the first cutting insulating layer CT1 may include the same insulating material. In some implementations, the upper separation pattern 152 and the second cutting insulating layer CT2 may include the same insulating material.

An upper insulating layer 160 may be provided on the gate capping pattern GP, the second interlayer insulating layer 52, the first and second cutting structures 130 and 140, and the separation structure 150. The upper insulating layer 160 may include an insulating material. In some implementations, the upper insulating layer 160 may be a multiple layer structure including a plurality of insulating layers.

A lower insulating layer 170 may be provided. The base pattern BP and the device isolation layer 11 may be provided on the lower insulating layer 170. The lower separation pattern 151 of the separation structure 150 may be provided on the lower insulating layer 170.

A first through via 110 and a second through via 120 may be provided. The first through via 110 may penetrate the first cutting structure 130 and the upper insulating layer 160 in the third direction D3. A lower portion of the first through via 110 may be provided within the first cutting structure 130. The lower portion of the first through via 110 may be surrounded by the first cutting structure 130.

The first through via 110 may be in contact with the separation structure 150 and the first cutting structure 130. The first through via 110 may be spaced apart from the first cutting insulating layer CT1 of the first cutting structure 130. The first through via 110 may be in contact with the second cutting insulating layer CT2 of the first cutting structure 130. The first through via 110 may be in contact with the upper separation pattern 152. The first through via 110 may be spaced apart from the lower separation pattern 151.

The second through via 120 may penetrate the second cutting structure 140 and the upper insulating layer 160 in the third direction D3. A lower portion of the second through via 120 may be provided within the second cutting structure 140. The lower portion of the second through via 120 may be surrounded by the second cutting structure 140.

The second through via 120 may be in contact with the second cutting structure 140. The second through via 120 may be spaced apart from the first cutting insulating layer CT1 of the second cutting structure 140. The second through via 120 may be in contact with the second cutting insulating layer CT2 of the second cutting structure 140. The second through via 120 may be spaced apart from the separation structure 150. The first through via 110 and the second through via 120 may include a conductive material.

The semiconductor patterns SP may include first semiconductor pattern SP1 connected to the third and fourth source/drain structures SD3 and SD4. The first semiconductor patterns SP1 may be in contact with the third and fourth source/drain structures SD3 and SD4.

The lower semiconductor pattern LSD of the first semiconductor patterns SP1 may be connected to the third and fourth lower source/drain patterns LSD3 and LSD4. The lower semiconductor pattern LSD of the first semiconductor patterns SP1 may be in contact with the third and fourth lower source/drain patterns LSD3 and LSD4. The upper semiconductor pattern USD of the first semiconductor patterns SP1 may be connected to the third and fourth upper source/drain patterns USD3 and USD4. The upper semiconductor patterns USD of the first semiconductor patterns SP1 may be in contact with the third and fourth upper source/drain patterns USD3 and USD4.

The gate structures GS may include a first gate structure GS1 overlapping the first semiconductor pattern SP1 in the third direction D3. The first gate structure GS1 may overlap the lower semiconductor pattern LSD and the upper semiconductor pattern USD of the first semiconductor patterns SP1 in the third direction D3.

The first cutting structure 130 may be provided between the first semiconductor pattern SP1 and the separation structure 150. The first cutting structure 130 may be provided between the first gate structure GS1 and the separation structure 150.

The first through via 110 may be provided between the first semiconductor pattern SP1 and the separation structure 150. The first through via 110 may be provided between the first gate structure GS1 and the separation structure 150.

An upper active contact UAC may be provided. The upper active contact UAC may be electrically connected to the upper source/drain pattern USD. The upper active contact UAC may be in contact with the upper source/drain pattern USD. In some implementations, a metal-silicide layer may be provided between the upper active contact UAC and the upper source/drain pattern USD. The upper active contact UAC may penetrate the upper insulating layer 160, the second interlayer insulating layer 52, and the upper liner 42 in the third direction D3. The upper active contact UAC may include a conductive material.

The upper active contacts UAC may include a first upper active contact UAC1 electrically connected to the first through via 110. The first upper active contact UAC1 may be in contact with the first through via 110. The first upper active contact UAC1 may include a portion P1 interposed between the first through via 110 and the first cutting insulating layer CT1 of the first cutting structure 130.

A lower active contact LAC may be provided. The lower active contact LAC may be electrically connected to the lower source/drain pattern LSD. The lower active contact LAC may be in contact with the lower source/drain pattern LSD. In some implementations, a metal-silicide layer may be provided between the lower active contact LAC and the lower source/drain pattern LSD. The lower active contact LAC may penetrate the base pattern BP and the device isolation layer 11 in the third direction D3. The lower active contact LAC may include a conductive material.

A lower via LV may be provided. The lower via LV may be electrically connected to the lower gate electrode GE1 of the gate structure GS. The lower via LV may be in contact with the lower gate electrode GE1 of the gate structure GS. The lower via LV may penetrate the device isolation layer 11 and the gate insulating layer GI in the third direction D3. The lower via LV may include a conductive material.

A lower conductive line CL may be provided in the lower insulating layer 170. The lower conductive line CL may be connected to the lower active contact LAC or the lower via LV. The lower conductive line CL may be in contact with the lower active contact LAC or the lower via LV. The lower conductive lines CL may include the lower conductive line CL connecting the first through via 110 and the lower active contact LAC. The lower conductive lines CL may include the lower conductive line CL that is in contact with the first through via 110 and the lower active contact LAC. The lower conductive line CL may include a conductive material.

A lower surface 130_L of the first cutting structure 130 and a lowermost portion, or lower surface, 150_Lof the separation structure 150 may be in contact with an upper surface 170_U of the lower insulating layer 170. A lower surface 110_L of the first through via 110 may be coplanar with the lower surface 130_L of the first cutting structure 130 and the lowermost portion, or lower surface, 150_L of the separation structure 150. The lowermost portion, or lower surface, 150_L of the separation structure 150 may be a lowermost portion of the lower separation pattern 151.

Levels of the lower surface 130_L of the first cutting structure 130, the lowermost portion, or lower surface, 150_L of the separation structure 150, and the lower surface 110_L of the second through via 110 may be lower than that of a lowermost portion LSD_L of the lower source/drain pattern LSD.

Levels of an upper surface 150_U of separation structure 150, an upper surface 130_U of first cutting structure 130, and an upper surface 110_U of first through via 110 may be higher than that of top surface USD_U of upper source/drain pattern USD.

Referring to FIG. 1E, the first cutting structure 130 may include an intervening portion IN interposed between the first through via 110 and the lower separation pattern 151 of the separation structure 150. An upper surface IN_U of the intervening portion IN may be in contact with a lower surface 152_L of the upper separation pattern 152. The lower surface 152_L of the upper separation pattern 152 may be in contact with an upper surface 151_U of the lower separation pattern 151. The upper surface IN_U of the intervening portion IN may be coplanar with the upper surface 151_U of the lower separation pattern 151. A level of the upper surface IN_U of the intervening portion IN may be the same as that of the upper surface 151_U of the lower separation pattern 151.

The intervening portion IN may include a first portion P11 in contact with the lower separation pattern 151 and a second portion P12 in contact with the first through via 110. An upper surface P11_U of the first portion P11 of the interposition IN and an upper surface P12_U of the second portion P12 of the interposition IN may be in contact with the lower surface 152_L of the upper separation pattern 152.

The first portion P11 of the intervening portion IN may be spaced apart from the first through via 110. The second portion P12 of the intervening portion IN may be spaced apart from the separation structure 150. The second portion P12 of the intervening portion IN may be spaced apart from the lower separation pattern 151. The first portion P11 and the second portion P12 of the intervening portion IN may include different insulating materials. The first portion P11 of the intervening portion IN may be a portion of the first cutting insulating layer CT1. The second portion P12 of the intervening portion IN may be a portion of the second cutting insulating layer CT2.

The first through via 110 may include a first sidewall 110_S1 in contact with the upper separation pattern 152 and a second sidewall 110_ S2 in contact with the second portion P12 of the intervening portion IN. The first sidewall 110_S1 and the second sidewall 110_ S2 of the first through via 110 may be coplanar. A sidewall including the first sidewall 110_S1 and the second sidewall 110_ S2 of the first through via 110 may be flat.

In some implementations, electrical characteristics of a P-type transistor and an N-type transistor may be improved as the lower separation pattern 151 may include a material that applies a compressive stress to the P-type first and second lower source/drain patterns LSD1 and LSD2, and the upper separation pattern 152 may include a material that apply a tensile stress to the N-type first and the second upper source/drain patterns USD1 and USD2.

In some implementations, as the first through via 110 is in contact with the upper separation pattern 152 and the second cutting insulating layer CT2, and is spaced apart from the lower separation pattern 151 and the first cutting insulating layer CT1, the first through via 110 may have a flat sidewall, and may have a symmetrical structure with respect to a line or plane extending in the third direction D3. Accordingly, a structural stability of the first through via 110 may be improved, and electrical characteristics may be improved.

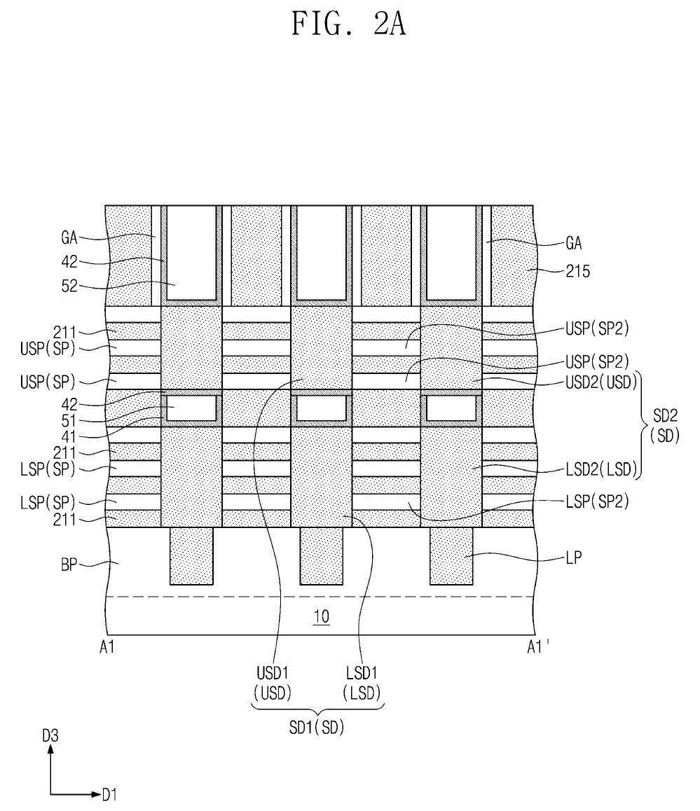

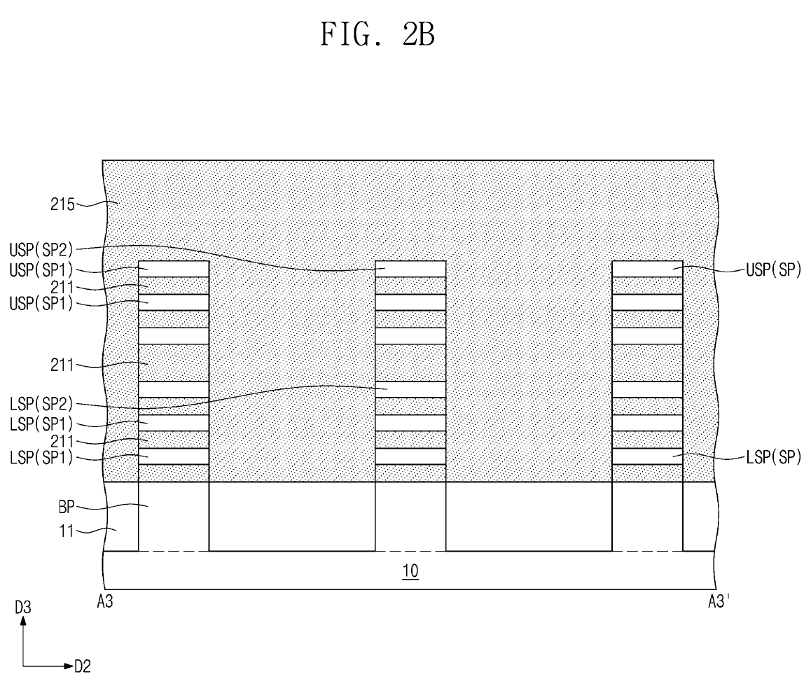

FIGS. 2A, 2B, 3A, 3B, 4A, 4B, 5A, 5B, 6A, 6B, 7A, 7B, 8A, 8B, 9A, 9B, 10A, 10B, 11A, 11B, 12A, 12B, and 12C are diagrams illustrating an example a method of manufacturing a semiconductor device, e.g., the semiconductor device of FIGS. 1A to 1E. The cross-sectional views of these figures correspond to the cross-sections A1-A1′, A2-A2′, and A3-A3′ of FIGS. 1B, 1C, and 1D.

Referring to FIGS. 2A and 2B, a substrate 10 may be provided. The base pattern BP, a sacrificial layer 211, the semiconductor pattern SP, the gate spacer GA, and a sacrificial pattern 215 may be formed.

The sacrificial layer 211 may overlap the semiconductor pattern SP in the third direction D3. A material included in the sacrificial layer 211 may have an etching selectivity with respect to a material included in the semiconductor pattern SP. As an example, the sacrificial layer 211 may include silicon-germanium, and the semiconductor pattern SP may include silicon.

The sacrificial pattern 215 may be provided on the semiconductor pattern SP and the sacrificial layer 211. The sacrificial pattern 215 may include, for example, polysilicon. The device isolation layer 11 may be formed.

A lower pattern LP may be formed in the base pattern BP. The lower pattern LP may be an epitaxial pattern formed by a selective epitaxial growth process. The lower pattern LP may include, for example, silicon (Si) or silicon-germanium (SiGe).

The source drain structure SD may be formed. Forming the source/drain structure SD may include forming the lower source/drain pattern LSD, and forming the upper source/drain pattern USD.

The lower source/drain pattern LSD may be formed on the lower pattern LP. The lower liner 41 and the first interlayer insulating layer 51 may be formed. The upper source/drain pattern USD may be formed. The upper liner 42 may be formed. The second interlayer insulating layer 52 may be formed.

The semiconductor patterns SP may include second semiconductor pattern SP2 between the first and second source/drain structures SD1 and SD2. The lower semiconductor pattern LSP of the second semiconductor patterns SP2 may be disposed between the first and second lower source/drain patterns LSD1 and LSD2. The upper semiconductor pattern USP of the second semiconductor patterns SP2 may be disposed between the first and second upper source/drain patterns USD1 and USD2. The second semiconductor pattern SP2 may be adjacent to the first semiconductor pattern SP1 in the second direction D2.

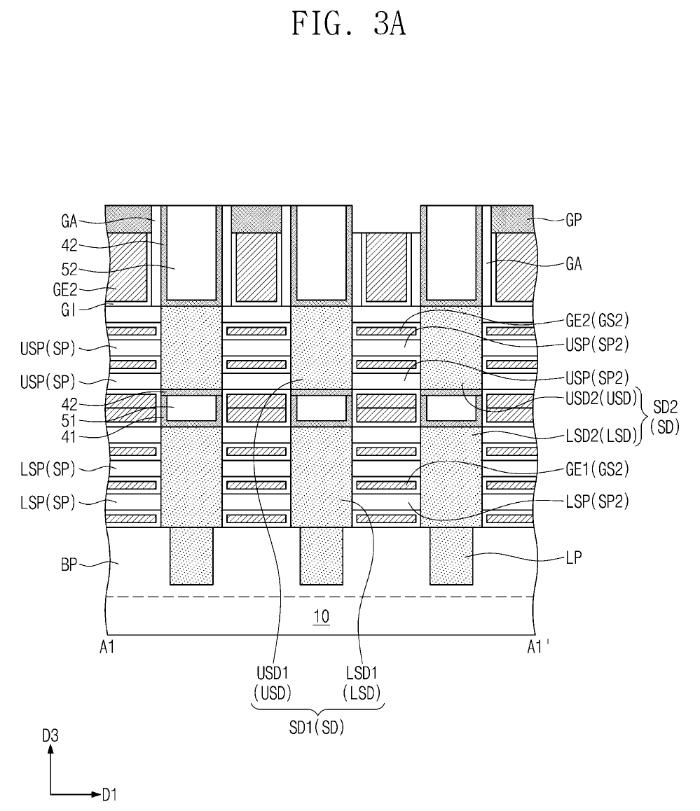

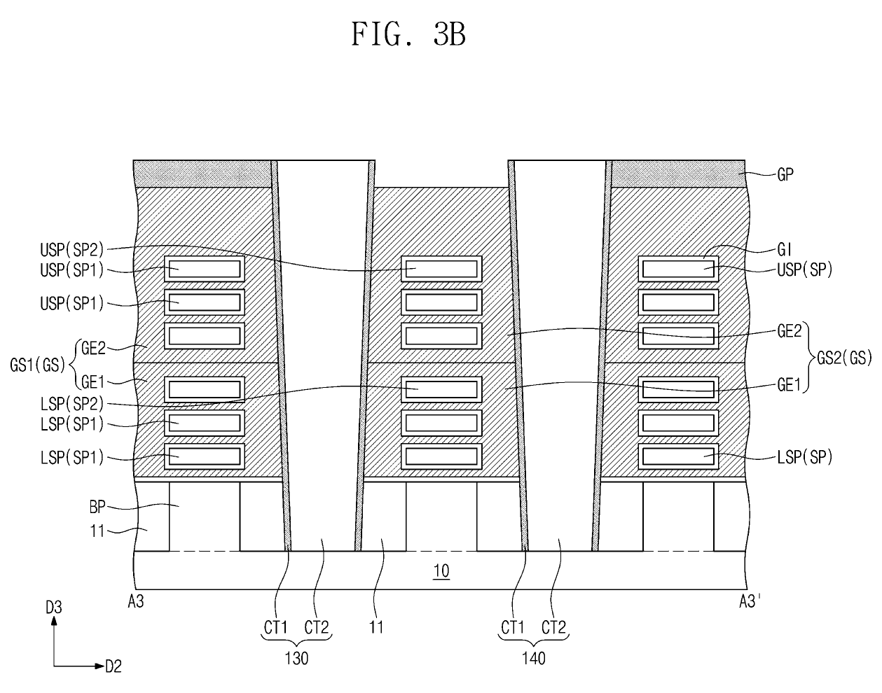

Referring to FIGS. 3A and 3B, the sacrificial pattern 215 and sacrificial layer 211 may be removed. A preliminary gate insulating layer, a preliminary gate electrode layer, and a preliminary gate capping layer may be formed in an empty space formed by removing the sacrificial pattern 215 and the sacrificial layer 211.

The first cutting structure 130 and the second cutting structure 140 may be formed. Forming the first cutting structure 130 and the second cutting structure 140 may include etching the preliminary gate insulating layer, the preliminary gate electrode layer, and the preliminary gate capping layer, and forming the first cutting structure 130 and the second cutting structure 140 in an empty space formed by etching the preliminary gate insulating layer, the preliminary gate electrode layer, and the preliminary gate capping layer.

The gate insulating layer GI may be formed by etching the preliminary gate insulating layer. The gate structure GS may be formed by etching the preliminary gate electrode layer. The gate capping pattern GP may be formed by etching the preliminary gate capping layer.

The gate structures GS may include a second gate structure GS2 between the first and second source/drain structures SD1 and SD2. The lower gate electrode GE1 of the second gate structure GS2 may be disposed between the first and second lower source/drain patterns LSD1 and LSD2. The upper gate electrode GE2 of the second gate structure GS2 may be disposed between the first and second upper source/drain patterns USD1 and USD2. The second gate structure GS2 may be adjacent to the first gate structure GS1 in the second direction D2. The second gate structure GS2 may overlap the second semiconductor pattern SP2 in the third direction D3.

The gate capping pattern GP on the second gate structure GS2 may be removed. The gate capping pattern GP on the second gate structure GS2 may be removed to expose the second gate structure GS2.

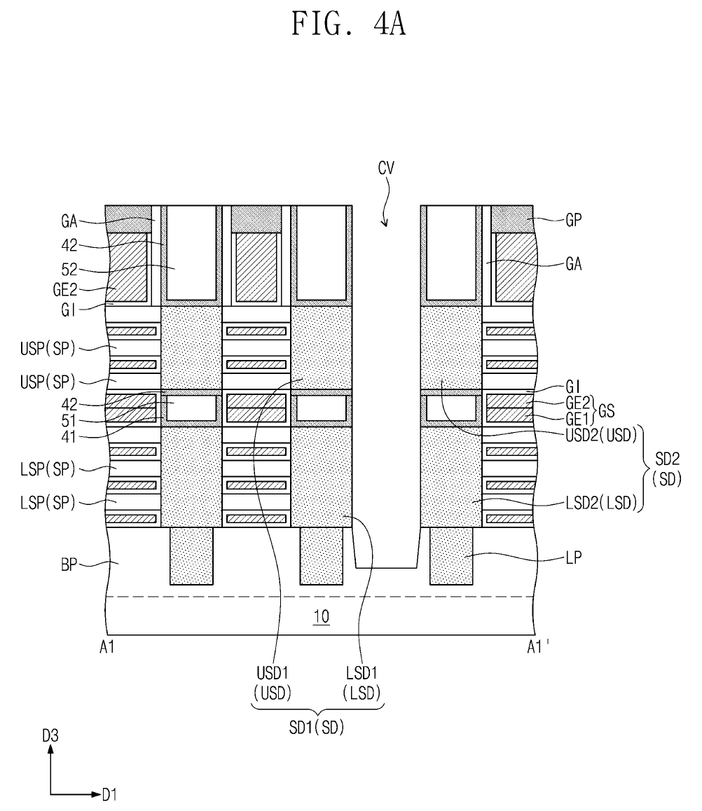

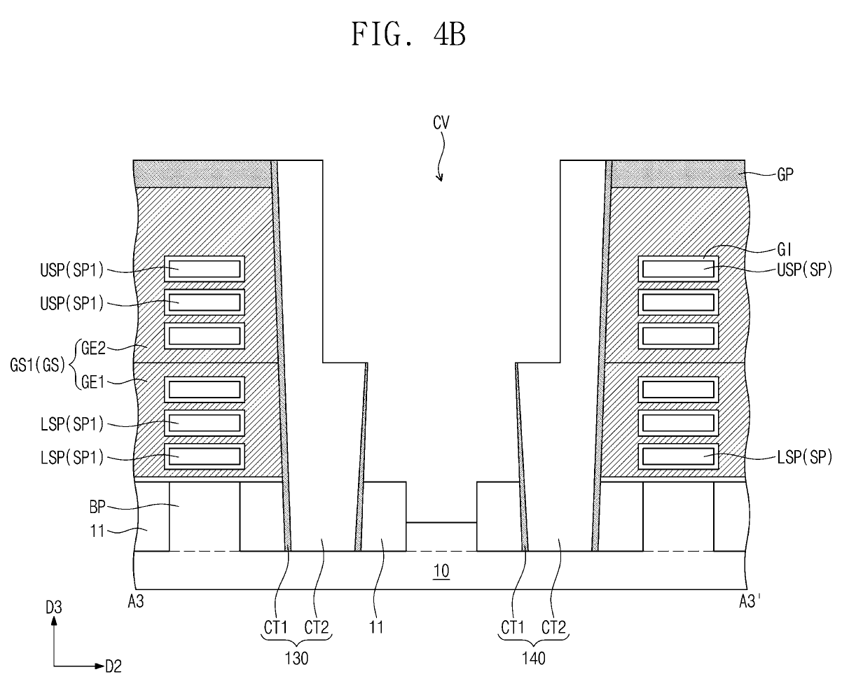

Referring to FIGS. 4A and 4B, a cavity CV may be formed. The cavity CV may be formed between the first and second source/drain structures SD1 and SD2. The cavity CV may be formed between the first and second cutting structures 130 and 140.

Forming the cavity CV may include removing the second gate structure GS2 and removing the second semiconductor pattern SP2. In the process of removing the second semiconductor pattern SP2, the gate insulating layer GI, the first cutting structure 130, and the second cutting structure 140 may be etched.

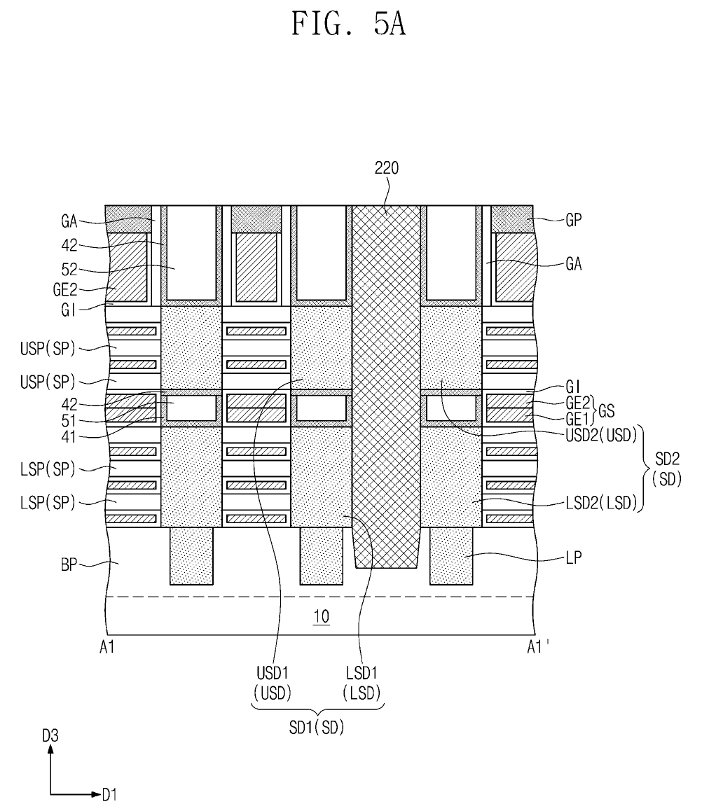

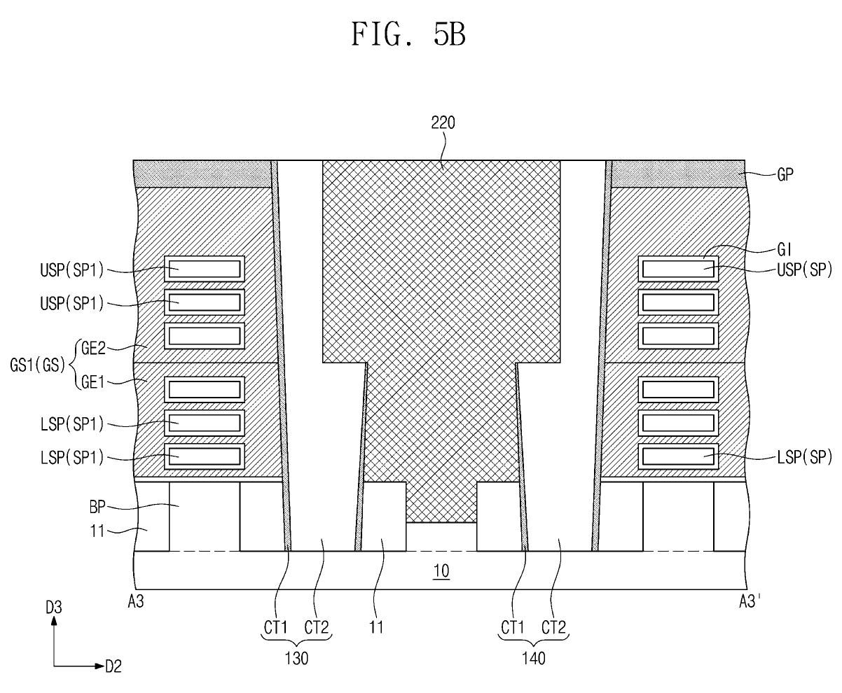

Referring to FIGS. 5A and 5B, a preliminary separation layer 220 may be formed in the cavity CV. The preliminary separation layer 220 may fill the cavity CV. The preliminary separation layer 220 may include an insulating material. For example, the preliminary separation layer 220 may include nitride. The preliminary separation layer 220 may be formed between the first and second source/drain structures SD1 and SD2. The preliminary separation layer 220 may be formed between the first and second cutting structures 130 and 140.

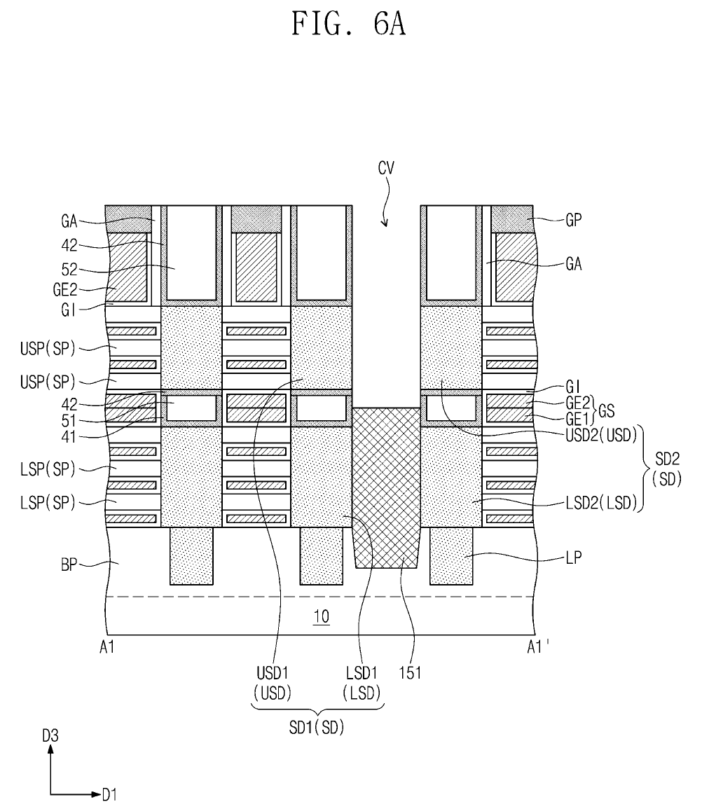

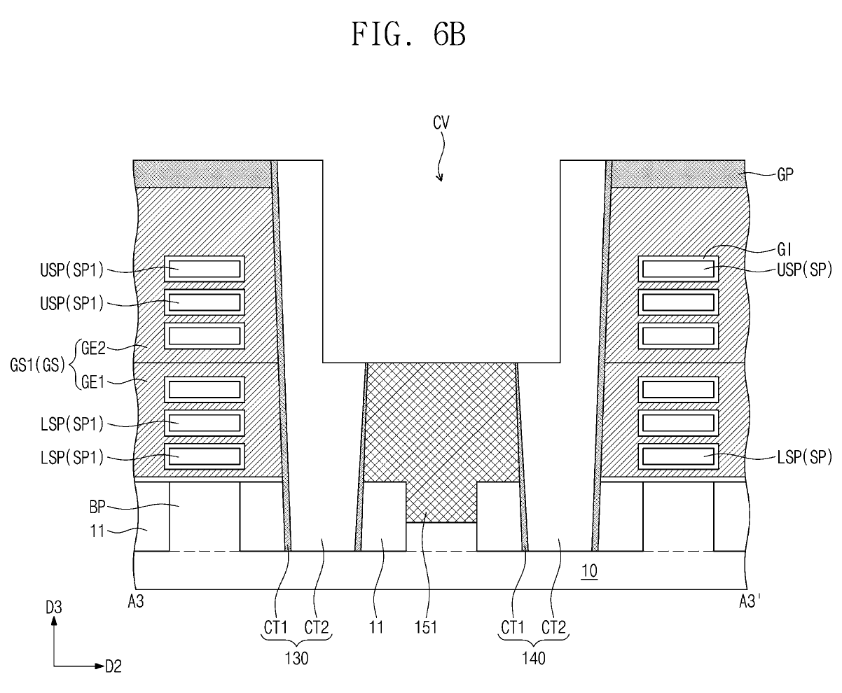

Referring to FIGS. 6A and 6B, the preliminary separation layer 220 may be etched. The preliminary separation layer 220 may be etched to form the lower separation pattern 151. The preliminary separation layer 220 may be etched so that an upper portion of the cavity CV may be opened again.

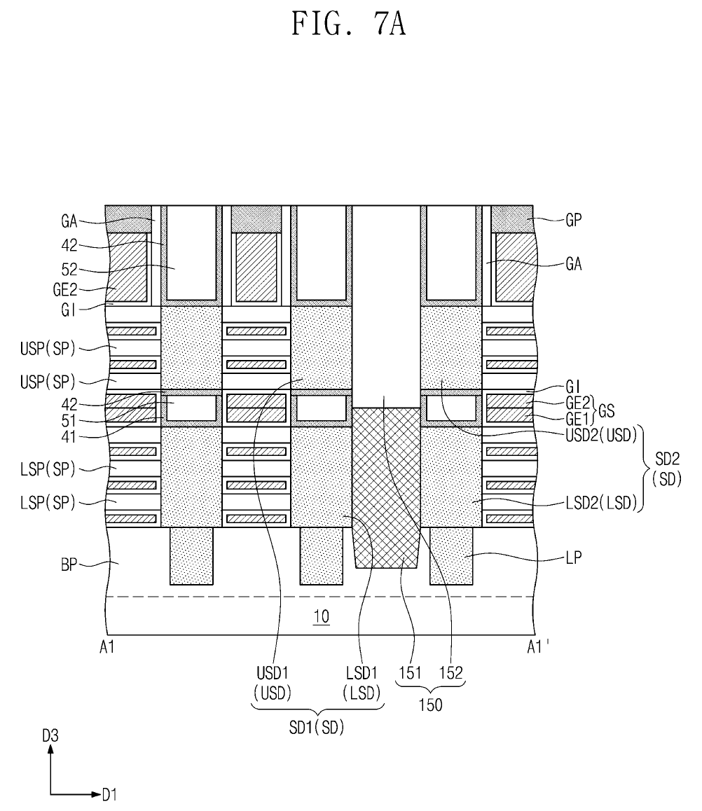

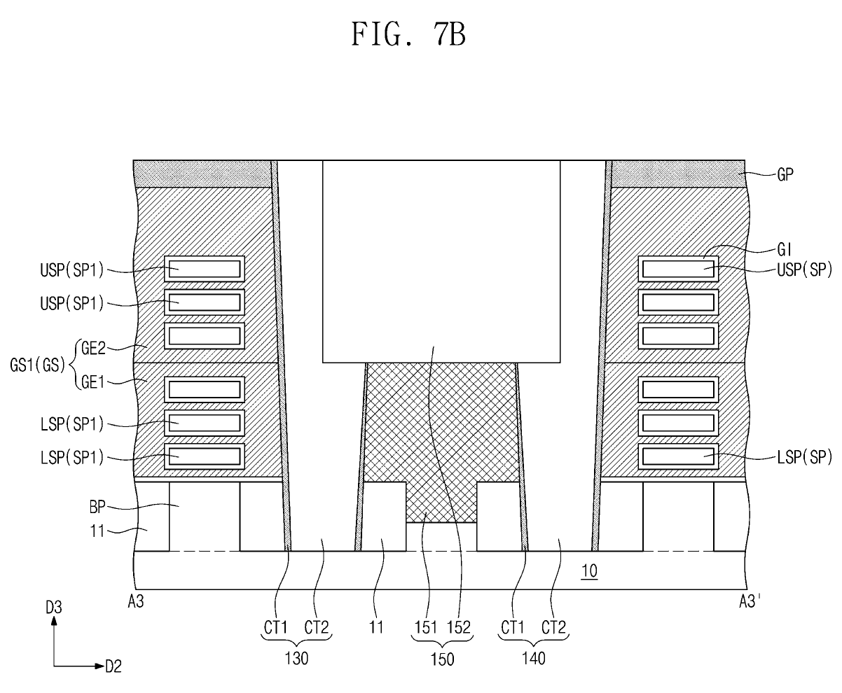

Referring to FIGS. 7A and 7B, the upper separation pattern 152 may be formed on the lower separation pattern 151. The upper separation pattern 152 may be formed in the upper portion of the cavity CV. The upper separation pattern 152 may fill the upper portion of the cavity CV.

In some implementations, forming the upper separation pattern 152 may include forming an upper separation layer covering the lower separation pattern 151, the first cutting structure 130, the second cutting structure 140, and the gate capping pattern GP, and removing an upper portion of the upper separation layer to form the upper separation pattern 151. The upper portion of the upper separation layer may be removed, for example, by a chemical mechanical polishing (CMP) process.

The upper separation pattern 152 may be formed, so that the separation structure 150 including a lower separation pattern 151 and an upper separation pattern 152 may be formed.

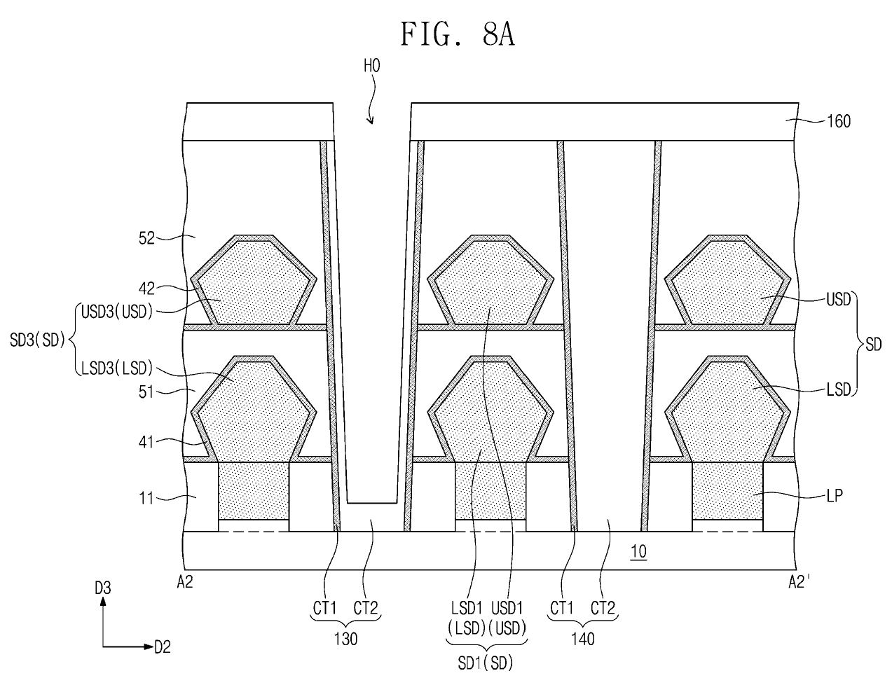

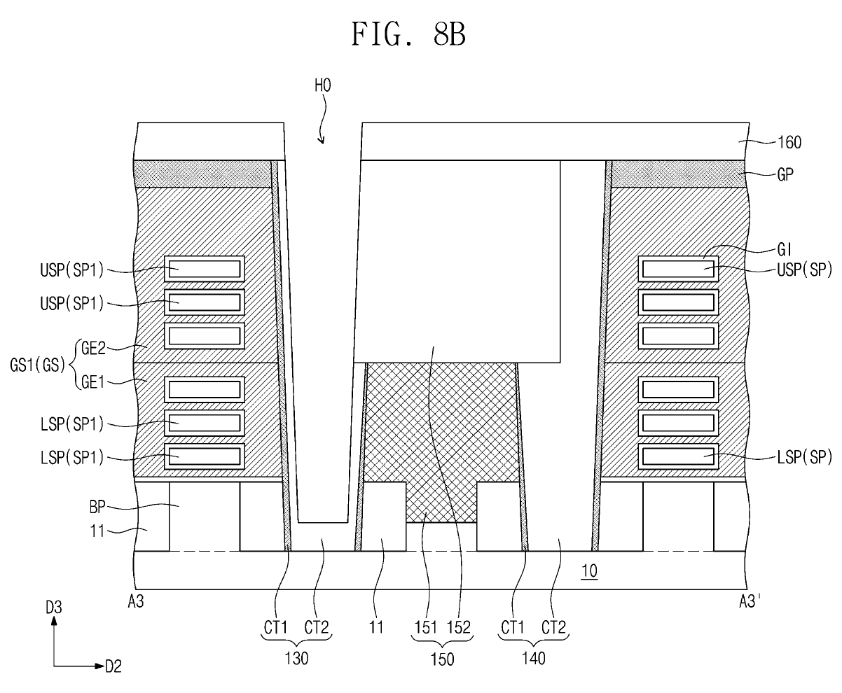

Referring to FIGS. 8A and 8B, the upper insulating layer 160 may be formed. The upper insulating layer 160, the upper separation pattern 152 of the separation structure 150, and the second cutting insulating layer CT2 of the first cutting structure 130 may be etched to form a hole HO. The hole HO may be defined by the second cutting insulating layer CT2 of the first cutting structure 130, the upper separation pattern 152 of the separation structure 150, and the upper insulating layer 160. The hole HO may be spaced apart from the first cutting insulating layer CT1 of the first cutting structure 130 and the lower separation pattern 151 of the separation structure 150.

In some implementations, in a process of forming the hole HO, the upper separation pattern 152 of the separation structure 150 and the second cutting insulating layer CT2 of the first cutting structure 130 may be etched together.

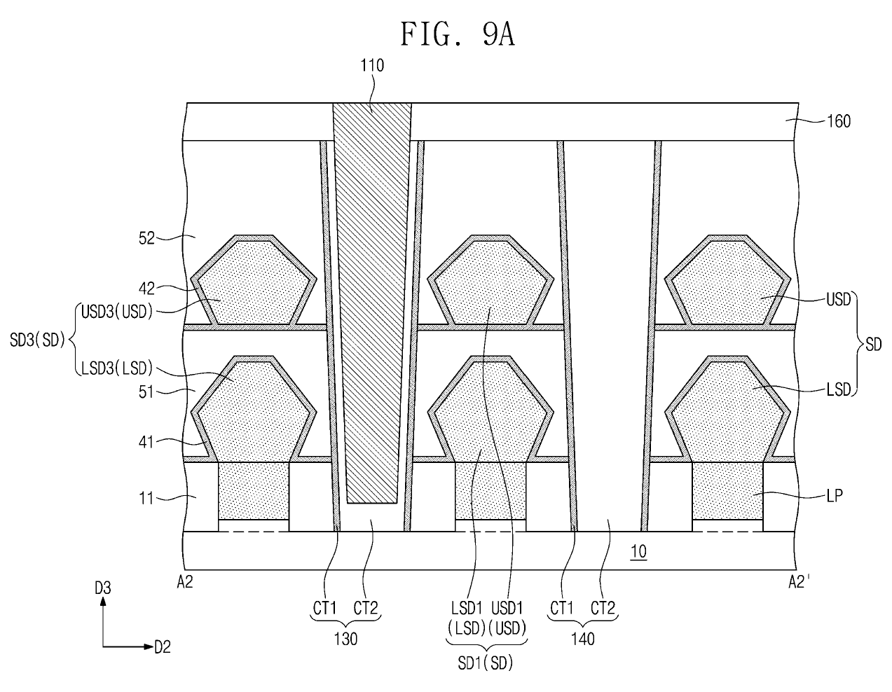

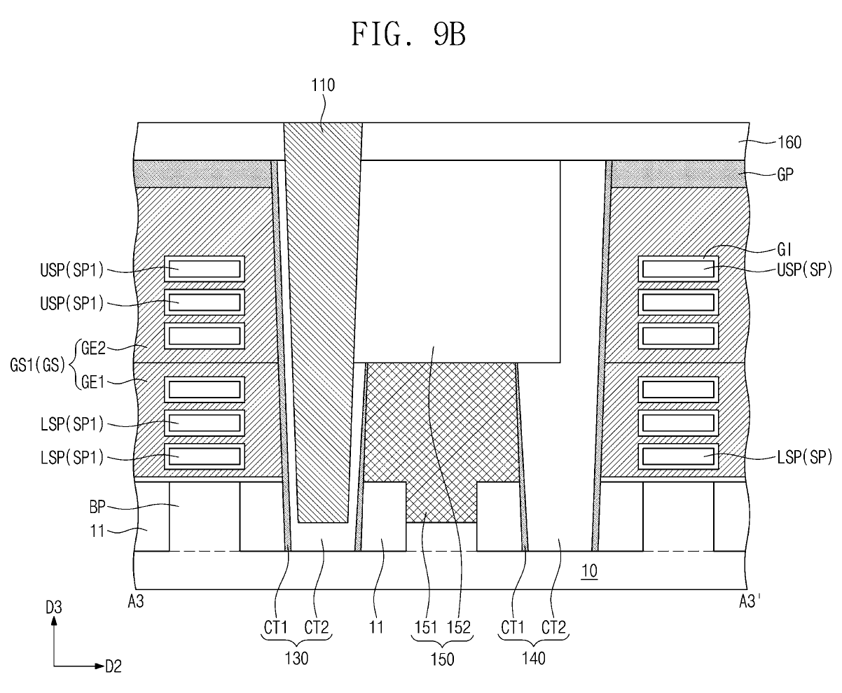

Referring to FIGS. 9A and 9B, the first through via 110 may be formed in the hole HO. In some implementations, forming the first through via 110 may include forming a conductive layer covering the upper insulating layer 160, the upper separation pattern 152, and the second cutting insulating layer CT2 of the first cutting structure 130, and removing an upper portion of the conductive layer to form the first through via 110. The upper portion of the conductive layer may be removed, for example, by a chemical mechanical polishing (CMP) process.

The second through via 120 (FIG. 1A) may be formed through a similar process as the first through via 110. In some implementations, the second through via 120 may be formed together with the first through via 110.

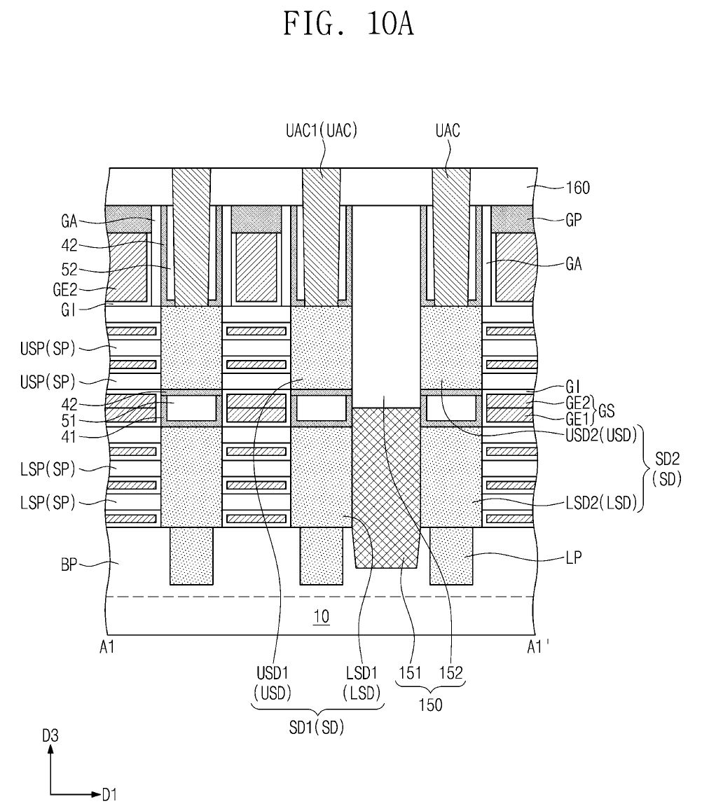

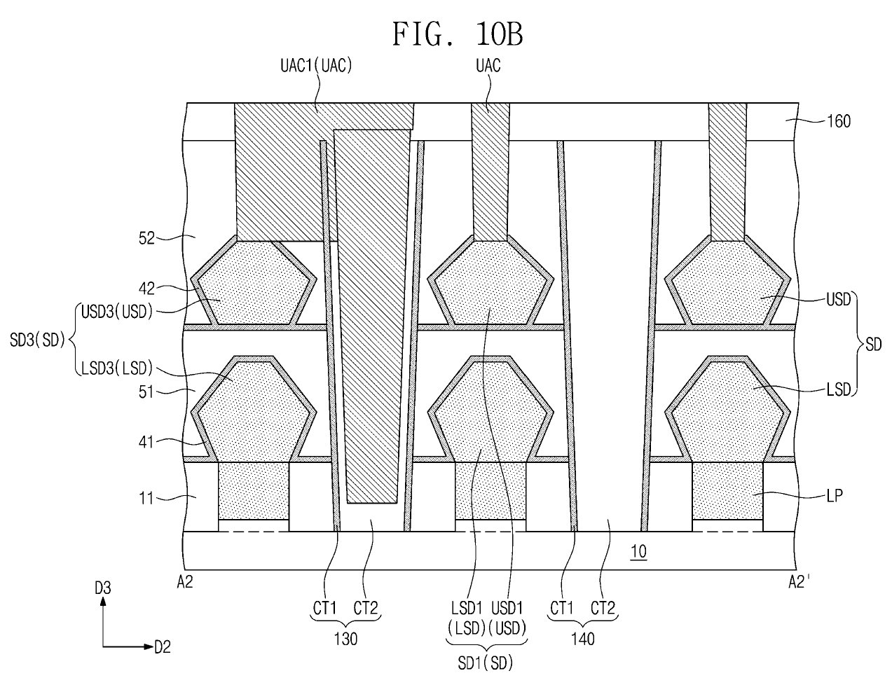

Referring to FIGS. 10A and 10B, the upper active contact UAC may be formed.

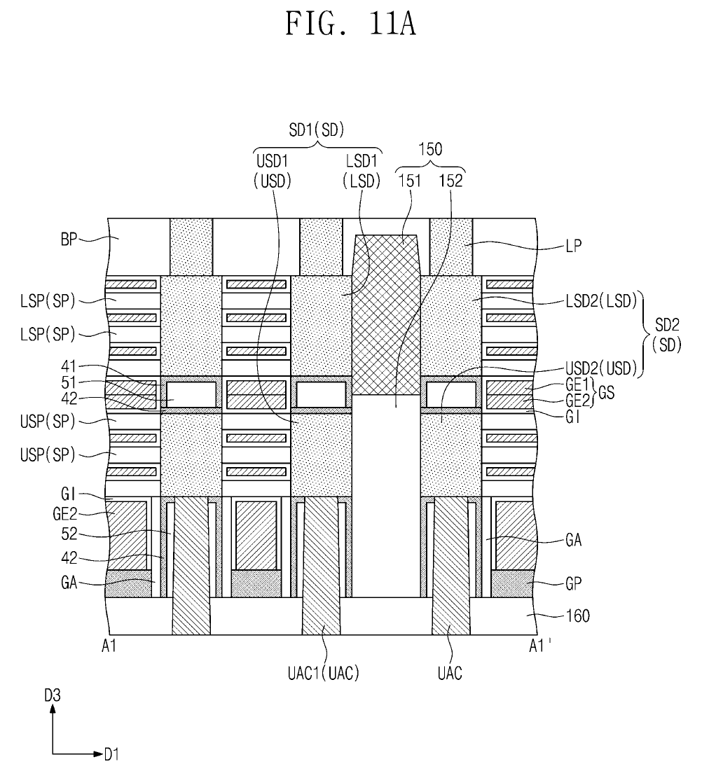

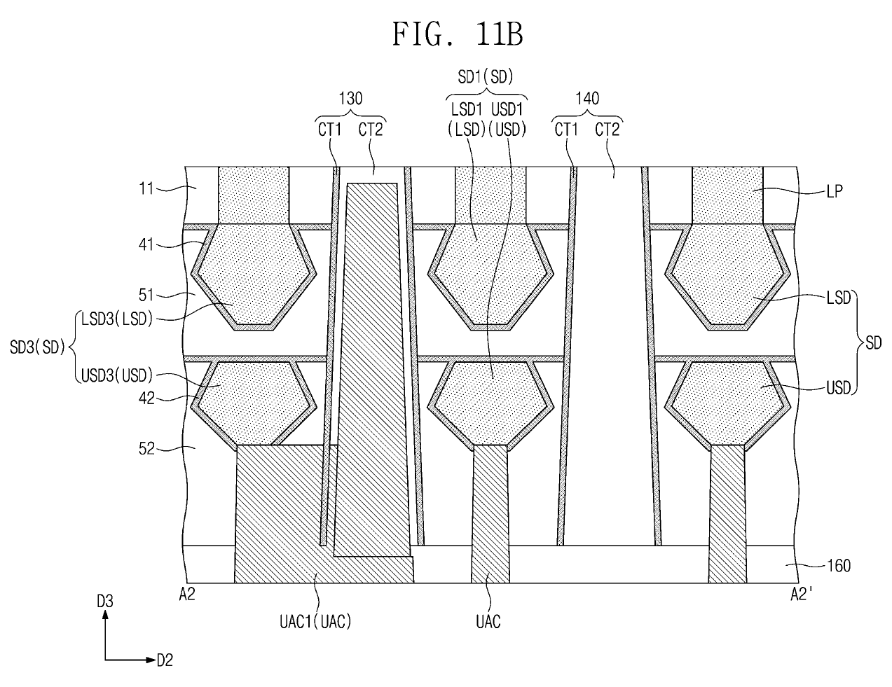

Referring to FIGS. 11A and 11B, the substrate 10 may be flipped. The substrate 10 may be removed. As an example, the substrate 10 may be removed by a chemical mechanical polishing (CMP) process. The substrate 10 may be removed to expose the device isolation layer 11, the first cutting structure 130, the second cutting structure 140, and the lower pattern LP.

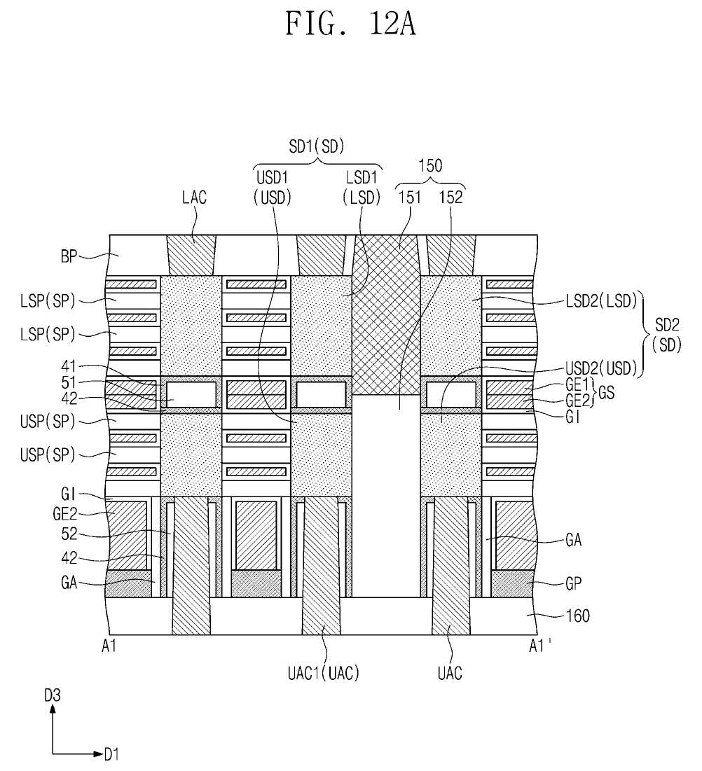

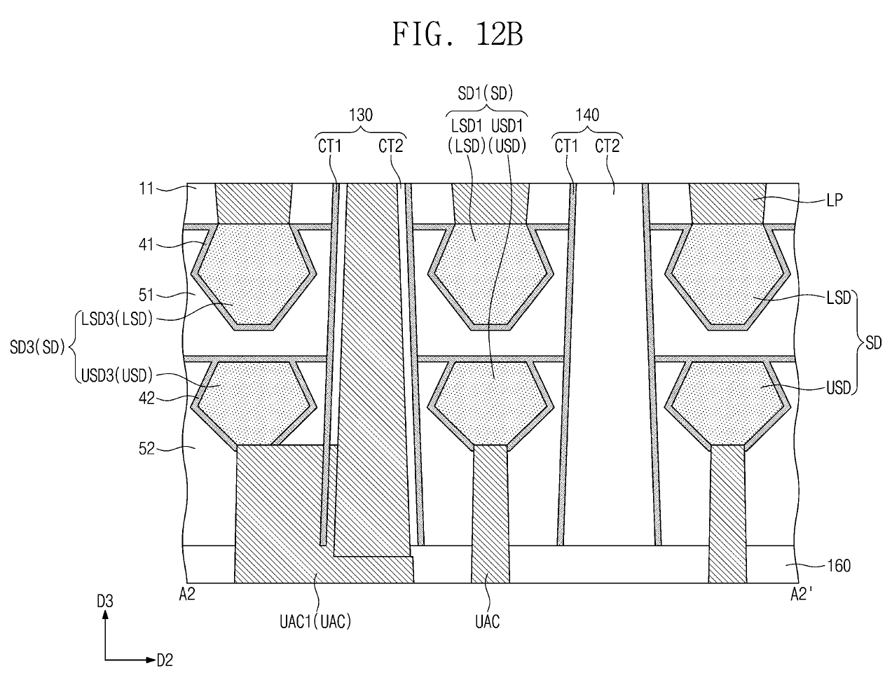

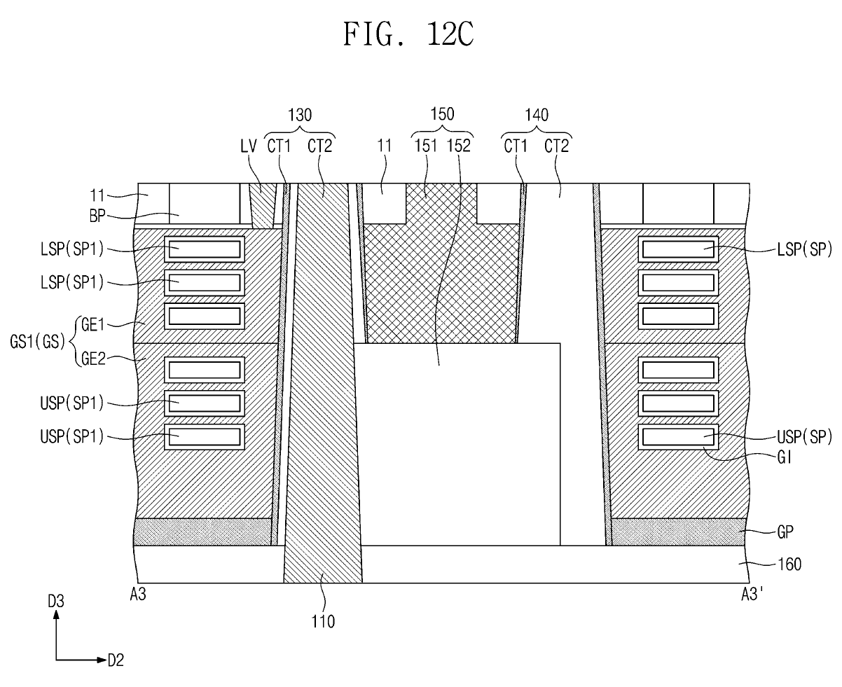

Referring to FIGS. 12A, 12B, and 12C, the lower pattern LP may be removed. The lower active contact LAC may be formed in an empty space formed by removing the lower pattern LP. The lower via LV may be formed.

Portions of the base pattern BP, the first cutting structure 130, the second cutting structure 140, and the device isolation layer 11 may be removed. The portions of the base pattern BP, the first cutting structure 130, the second cutting structure 140, and the device isolation layer 11 may be removed to expose the first through via 110 and the lower separation pattern 151.

Referring to FIGS. 1A, 1B, 1C, and 1D, the lower insulating layer 170 may be formed on the lower active contact LAC, the lower via LV, the first cutting structure 130, the second cutting structure 140, the lower separation pattern 151, the device isolation layer 11, and the base pattern BP. The lower conductive line CL may be formed in the lower insulating layer 170.

In some implementations, the upper separation pattern 152 and the second cutting insulating layer CT2 may be etched in the process of forming the hole HO, and the lower separation pattern 151 and the first cutting insulating layer CT1 may not be etched. As the upper separation pattern 152 and the second cutting insulating layer CT2 including the same material are etched, a difficulty of an etching process may be lowered, and a structural stability of the first through via 110 may be improved.

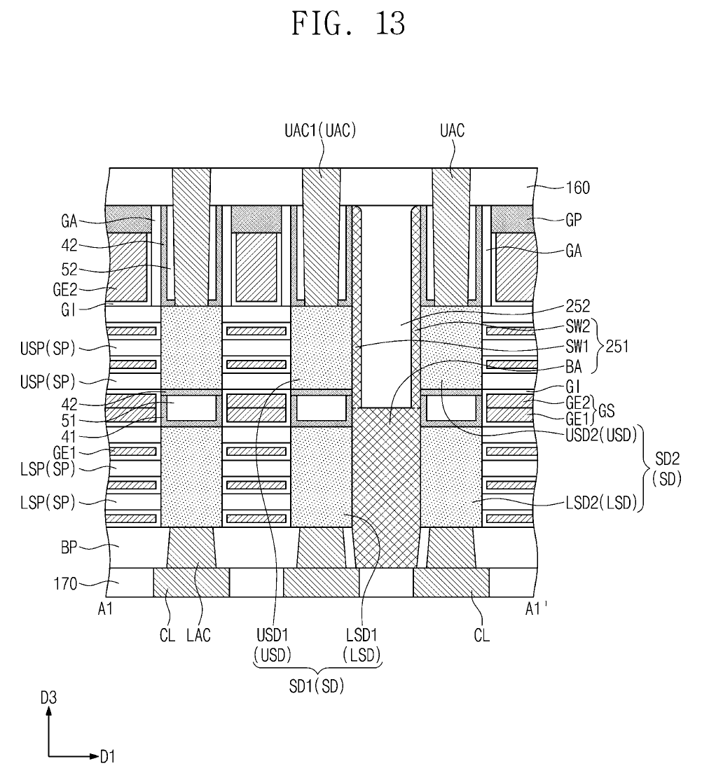

FIG. 13 is a cross-sectional view of an example of a semiconductor device. The semiconductor device of FIG. 13 is similar to the semiconductor device of FIGS. 1A - 1E, and the following description focuses on differences therebetween; it will be understood that the same or similar description provided for FIGS. 1A - 1E applies to FIG. 13, except where indicated otherwise or suggested otherwise by context.

Referring to FIG. 13, a lower separation pattern 251 may include a base portion BA, a first sidewall portion SW1, and a second sidewall portion SW2. The base portion BA may be disposed between the first and second lower source/drain patterns LSD1 and LSD2. The base portion BA may be in contact with the first and second lower source/drain patterns LSD1 and LSD2. The base portion BA may be disposed at the same level as the first and second lower source/drain patterns LSD1 and LSD2. The first sidewall portion SW1 and the second sidewall portion SW2 may protrude from the base portion BA in the third direction D3.

The first sidewall portion SW1 may be in contact with the first upper source/drain pattern USD1. The first sidewall portion SW1 may be provided between the upper separation pattern 252 and the first upper source/drain pattern USD1. The first sidewall portion SW1 may be disposed at the same level as the first upper source/drain pattern USD1.

The second sidewall portion SW2 may be in contact with the second upper source/drain pattern USD2. The second sidewall portion SW2 may be provided between the upper separation pattern 252 and the second upper source/drain pattern USD2. The second sidewall portion SW2 may be disposed at the same level as the second upper source/drain pattern USD2.

The upper separation pattern 252 may be spaced apart from the first and second upper source/drain patterns USD1 and USD2. The upper separation pattern 252 may be provided between the first sidewall portion SW1 and the second sidewall portion SW2. The upper separation pattern 252 may be in contact with a sidewall of the first sidewall portion SW1, a sidewall of a second sidewall portion SW2, and an upper surface of the base portion BA.

In some implementations, based on the use of a separation structure that applies a compressive stress to a P-type source/drain pattern and applies a tensile stress to an N-type source/drain pattern, electrical characteristics of both the P-type transistor and the N-type transistor may be improved.

In addition, in some implementations, the semiconductor devices described herein may have improved structural stability of a through via.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure as set forth in the following claims.

What is claimed is:

1. A semiconductor device comprising:
a first lower source/drain pattern;
a second lower source/drain pattern spaced apart from the first lower source/drain pattern in a first direction;
a first upper source/drain pattern overlapping the first lower source/drain pattern along a direction perpendicular to the first direction;
a second upper source/drain pattern overlapping the second lower source/drain pattern along the direction perpendicular to the first direction;
a lower separation pattern between the first lower source/drain pattern and the second lower source/drain pattern;
an upper separation pattern between the first upper source/drain pattern and the second upper source/drain pattern; and
a through via in contact with the upper separation pattern and spaced apart from the lower separation pattern,
wherein the upper separation pattern and the lower separation pattern comprise different insulating materials.

2. The semiconductor device of claim 1, wherein a level of a lower surface of the through via is lower than a level of a lower surface of the first lower source/drain pattern and a level of a lower surface of the second lower source/drain pattern, and
wherein a level of an upper surface of the through via is higher than a level of an upper surface of the first upper source/drain pattern and a level of an upper surface of the second upper source/drain pattern.

3. The semiconductor device of claim 1, wherein the lower separation pattern is in contact with the first and second lower source/drain patterns.

4. The semiconductor device of claim 3, wherein the upper separation pattern is in contact with the first and second upper source/drain patterns.

5. The semiconductor device of claim 3, wherein the upper separation pattern is spaced apart from the first and second upper source/drain patterns.

6. The semiconductor device of claim 1, comprising:
a third lower source/drain pattern spaced apart from the first lower source/drain pattern in a second direction intersecting the first direction;
lower semiconductor patterns connected to the third lower source/drain pattern;
a gate structure overlapping the lower semiconductor patterns along the direction perpendicular to the first direction; and
a cutting structure between the lower separation pattern and the gate structure,
wherein the through via extends in the cutting structure.

7. The semiconductor device of claim 6, wherein the cutting structure comprises a first cutting insulating layer and a second cutting insulating layer in contact with the first cutting insulating layer, and
wherein the second cutting insulating layer and the upper separation pattern comprise a same insulating material.

8. The semiconductor device of claim 1, wherein the upper separation pattern comprises a first insulating material configured to apply a tensile stress to the first and second lower source/drain patterns, and
wherein the lower separation pattern comprises a second insulating material configured to apply a compressive stress to the first and second upper source/drain patterns.

9. A semiconductor device comprising:
a first source/drain structure;
a second source/drain structure spaced apart from the first source/drain structure in a first direction;
a third source/drain structure spaced apart from the first source/drain structure in a second direction intersecting the first direction;
a separation structure between the first source/drain structure and the second source/drain structure;
semiconductor patterns connected to the third source/drain structure;
a gate structure overlapping the semiconductor patterns along a direction perpendicular to the first direction;
a cutting structure between the gate structure and the separation structure; and
a through via extending in the cutting structure.

10. The semiconductor device of claim 9, wherein the through via is in contact with the separation structure.

11. The semiconductor device of claim 9, wherein the separation structure comprises a lower separation pattern and an upper separation pattern on the lower separation pattern, and
wherein the lower separation pattern and the upper separation pattern comprise different insulating materials.

12. The semiconductor device of claim 11, wherein the upper separation pattern is in contact with the through via, and
wherein the lower separation pattern is spaced apart from the through via.

13. The semiconductor device of claim 11, wherein the cutting structure comprises an intervening portion between the through via and the lower separation pattern, and
wherein an upper surface of the intervening portion is in contact with a lower surface of the upper separation pattern.

14. The semiconductor device of claim 13, wherein the intervening portion comprises a first portion in contact with the lower separation pattern and a second portion in contact with the through via,
wherein the first portion of the intervening portion is spaced apart from the through via,
wherein the second portion of the intervening portion is spaced apart from the lower separation pattern, and
wherein the first portion and the second portion comprise different insulating materials.

15. The semiconductor device of claim 14, wherein the through via comprises a first sidewall in contact with the upper separation pattern and a second sidewall in contact with the second portion of the intervening portion, and
wherein the first sidewall and the second sidewall of the through via are coplanar.

16. The semiconductor device of claim 11, wherein the upper separation pattern comprises an oxide, and
wherein the lower separation pattern comprises a nitride.

17. A semiconductor device comprising:
a first lower source/drain pattern;
a second lower source/drain pattern spaced apart from the first lower source/drain pattern in a first direction;
a third lower source/drain pattern spaced apart from the first lower source/drain pattern in a second direction intersecting the first direction;
a first upper source/drain pattern overlapping the first lower source/drain pattern along a direction perpendicular to the first direction;
a second upper source/drain pattern overlapping the second lower source/drain pattern along the direction perpendicular to the first direction;
a third upper source/drain pattern overlapping the third lower source/drain pattern along the direction perpendicular to the first direction;
a lower separation pattern between the first lower source/drain pattern and the second lower source/drain pattern;
an upper separation pattern between the first upper source/drain pattern and the second upper source/drain pattern, wherein the lower separation pattern and the upper separation pattern comprise different insulating materials;
lower semiconductor patterns connected to the third lower source/drain pattern;
upper semiconductor patterns connected to the third upper source/drain pattern;
a gate structure overlapping the lower semiconductor patterns and the upper semiconductor patterns along the direction perpendicular to the first direction; and
a through via between the first and third lower source/drain patterns, between the first and third upper source/drain patterns, between the lower separation pattern and the gate structure, and between the upper separation pattern and the gate structure.

18. The semiconductor device of claim 17, comprising lower active contacts connected to the first to third lower source/drain patterns; and
upper active contacts connected to the first to third upper source/drain patterns,
wherein the through via is electrically connected to at least one of the lower active contacts and to at least one of the upper active contacts.

19. The semiconductor device of claim 17, wherein the lower separation pattern comprises:
a base portion between the first lower source/drain pattern and the second lower source/drain pattern;
a first sidewall portion between the upper separation pattern and the first upper source/drain pattern; and
a second sidewall portion between the upper separation pattern and the second upper source/drain pattern.

20. The semiconductor device of claim 19, wherein the upper separation pattern is in contact with an upper surface of the base portion, a sidewall of the first sidewall portion, and a sidewall of the second sidewall portion.
